(19) United States
(12) Patent Application Publication
(10) Pub. No.: US 2003/0137805 A1
(43) Pub. Date: Jul. 24, 2003

(54) LCD displayer device having wireless LAN card connector

(76) Inventor: Roger Wu, Hsin Chuang City (TW)

Correspondence Address: Roger Wu, P.O. Box 4-67, Hsin Chuang, Taipei, 242, TW

(21) Appl. No.: 10/055,231

(22) Filed: Jan. 18, 2002

(51) Int. Cl. H05K 5/00

(52) U.S. Cl. 361/686; 361/681

(57) ABSTRACT

A displayer device includes a housing having an outer peripheral wall, and having a socket opening formed in the outer peripheral wall, and having a displayer screen disposed in the front portion, a socket engaged into the socket opening, and a wireless LAN card selectively engaging into the socket opening of the housing for coupling or plugging to the socket. A computer may be pivotally coupled to the housing. A USB device may be disposed in the housing or in the computer and coupled to the socket with one or more data buses.

### BACKGROUND OF THE INVENTION

1. Field of the Invention

The present invention relates to a displayer device and more particularly to a liquid crystal display (LCD) displayer device having a coupler or a connector or a socket for coupling a wireless local area network (LAN) card thereto.

2. Description of the Prior Art

Typical displayer devices, such as the LCD displayer devices or the portable computers comprise a wireless LAN device or card provided therein, and an antenna coupled to the wireless LAN device or card with one or more radio frequency (RF) cables. However, the RF cables may be used for transmitting analog signals, and may not be provided for transmitting digital signals. In addition, a great loss of the signals through the RF cables is great such that the signals may not be clearly sent or transmitted through the RF cables, and such that the signals may not be clearly received through the RF cables.

The so-called personal computer memory card international association (PCMICA) may be used and plugged to the typical web pad, for entering into various kinds of networks. However, more than fifty (50) cables or electric wires are required for coupling the PCMICA to the web pad, such that the PCMICA may not be used for coupling to the other computer facilities.

The present invention has arisen to mitigate and/or obviate the afore-described disadvantages of the conventional displayer devices.

### SUMMARY OF THE INVENTION

The primary objective of the present invention is to provide an LCD displayer device including a coupler or a connector or a socket for coupling a wireless local area network (LAN) card thereto.

In accordance with one aspect of the invention, there is provided a displayer device comprising a housing including an outer peripheral wall having a socket opening formed therein, and including a displayer screen provided thereon, a socket engaged into the socket opening, and a wireless LAN card selectively engaging into the socket opening of the housing for coupling to the socket.

The housing further includes a USB device disposed thereon, and at least one data bus coupling the USB device to the socket.

A computer body is further provided and pivotally coupled to the housing, a USB device is disposed in the computer body, and at least one data bus may couple the USB device to the socket. The provision and engagement of the socket in the socket opening or the channel of the housing may greatly reduce the volume of the computer body.

The housing includes a rear wall and includes a channel formed therein, the socket opening is opened through the rear wall of the housing and communicating with the channel of the housing, the socket is engaged in the channel of the housing.

Further objectives and advantages of the present invention will become apparent from a careful reading of a detailed description provided hereinbelow, with appropriate reference to accompanying drawings.

### BRIEF DESCRIPTION OF THE DRAWINGS

FIG. 1 is a partial exploded view illustrating a displayer device in accordance with the present invention having a wireless LAN card attachable or connectable to the displayer device;

FIG. 2 is a partial exploded view similar to FIG. 1, illustrating the other embodiment of the displayer device; and

FIG. 3 is a perspective view illustrating a further embodiment of the displayer device.

### DETAILED DESCRIPTION OF THE PREFERRED EMBODIMENT

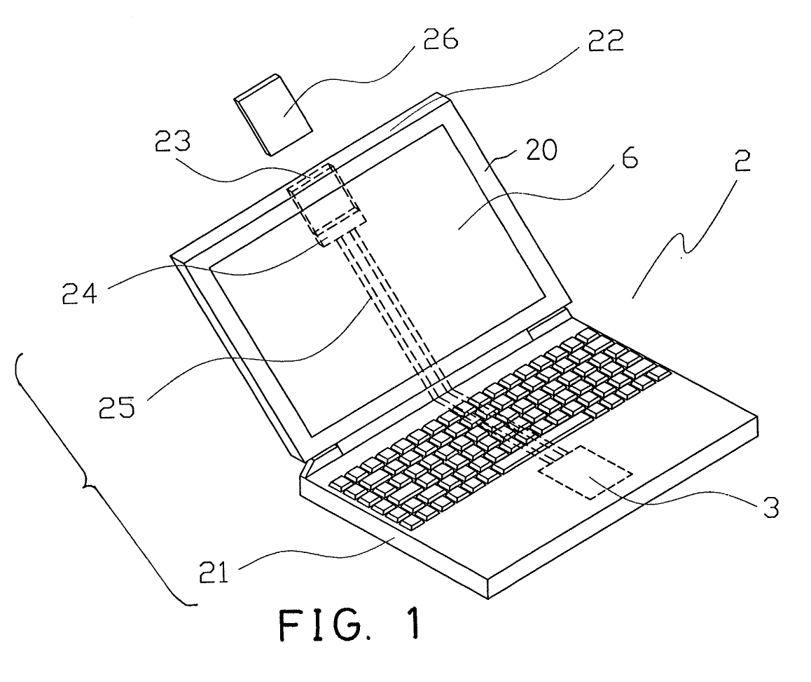

Referring to the drawings, and initially to FIG. 1, a displayer device in accordance with the present invention comprises a housing 20, such as a cover housing 20 of a portable computer 2, and pivotally or rotatably coupled to a computer body 21. The cover housing 20 includes a displayer device or a screen provided therein, such as the LCD displayer device 6 provided therein for displaying purposes. The cover housing 20 includes a free edge or an outer peripheral surface or an outer wall 22 having a socket opening 23 formed therein, and includes a socket 24 provided and disposed in the socket opening 23 of the housing 20.

A processor device, or an interface, or an integrated circuit, or a universal serial bus (USB) interface or card or device 3 is disposed in the computer body 21, and is coupled to the socket 24 with one or more wires or cables or data buses 25 which may be used for transmitting digital data. It is to be noted that the data buses 25 is greatly cheaper than that of the RF cables, and is such as ⅕ of the cost of that of the RF cables. Furthermore, the digital data or the other signals transmitted through the data buses 25 have less loss, for allowing the data or the signals to be clearly sent or transmitted through the data buses 25.

A wireless LAN device or card 26, such as the USB wireless LAN device or card 26 may further be provided and engaged into the socket opening 23 of the housing 20, and may be coupled or plugged to the socket 24 for coupling to the USB device 3. The provision or the formation of the socket opening 23 in the housing 20, and the provision and engagement of the socket 24 in the socket opening 23 of the housing 20 may greatly reduce the volume of the computer body 21. In addition, the data buses 25 may couple the wireless LAN card 26 to the USB device 3 without much loss, such that the socket 24 may be provided in a distance far away from the USB device 3. The socket 24 may be used for coupling to the wireless LAN card 26, or the other peripheral facilities, such as the digital cameras.

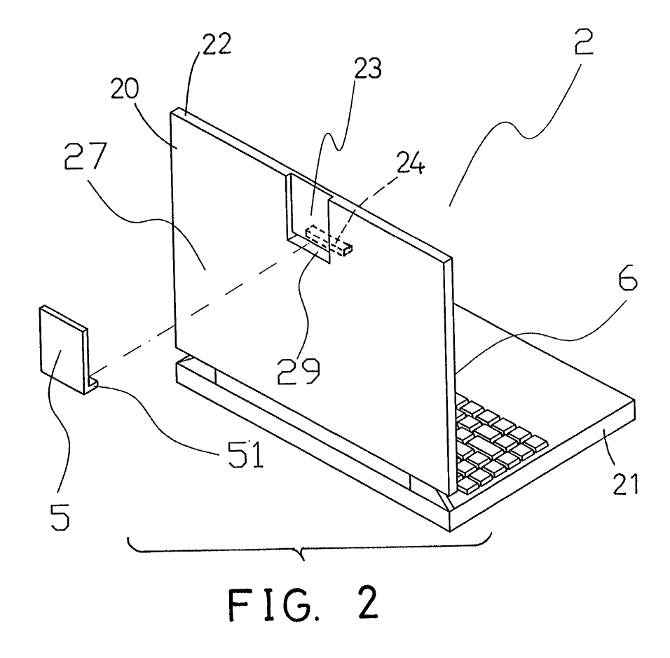

Referring next to FIG. 2, alternatively, the socket opening 23 may be opened through the rear wall 27 of the housing 20 and the upper or outer peripheral wall 22 of the housing 20, and may include a channel 29 formed therein and communicating with the socket opening 23 of the housing 20 for engaging or receiving the socket 24 therein. The other type of wireless LAN device or card 5 may thus be engaged into the socket opening 23, and may include a lateral connector 51 for engaging into the channel 29 of the housing 20 and for plugging to the socket 24.

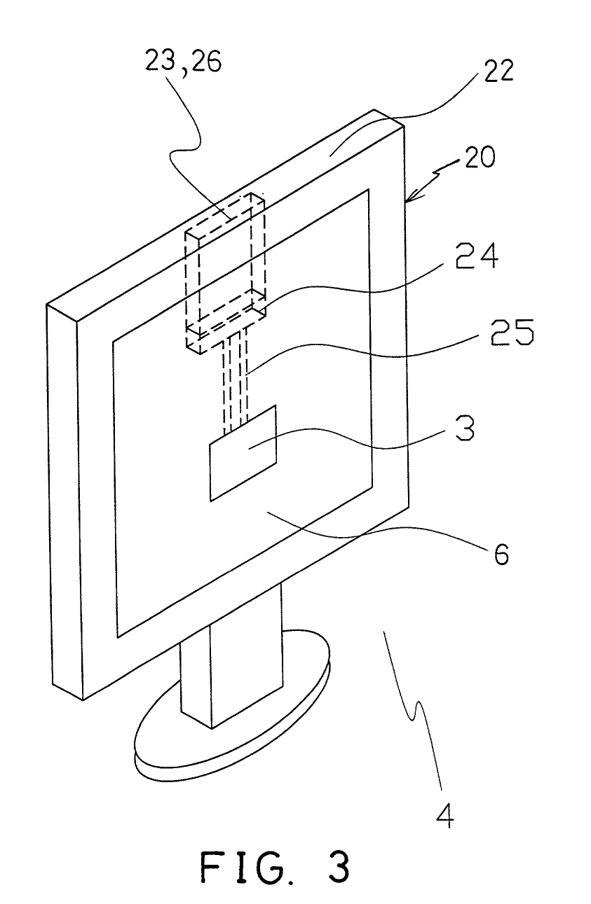

Referring next to FIG. 3, the housing 20 may include the USB device 3 directly engaged therein and coupled to the socket 24 with the data buses 25, and may also include a socket opening 23 for receiving or plugging the wireless LAN device or card 26. The housing 20 may also include the LCD displayer device 6 provided therein. The provision and the engagement of the USB device 3 and the socket 24 and the wireless LAN device or card 26 in the housing 20 may be used as the web pad 4.

It is to be noted that the typical displayer devices, particularly the LCD displayer devices have only the LCD screen or displayer provided therein, and may not be used for coupling to the other facilities, such as the wireless LAN card 26, 5. The typical displayer devices should be coupled to the computer body 21 before they may be used or operated.

Accordingly, the displayer device in accordance with the present invention includes a coupler or a connector or a socket for coupling a wireless local area network (LAN) card thereto.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A displayer device comprising:
a housing including an outer peripheral wall having a socket opening formed therein, and including a displayer screen provided thereon,
a socket engaged into said socket opening, and
a wireless LAN card selectively engaging into said socket opening of said housing for coupling to said socket.

2. The displayer device according to claim 1, wherein said housing further includes a USB device disposed thereon, and at least one data bus coupling said USB device to said socket.

3. The displayer device according to claim 1 further comprising a computer body pivotally coupled to said housing, a USB device disposed in said computer body, and at least one data bus coupling said USB device to said socket.

4. The displayer device according to claim 1, wherein said housing includes a rear wall and includes a channel formed therein, said socket opening is opened through said rear wall of said housing and communicating with said channel of said housing, said socket is engaged in said channel of said housing.
